(19) United States
(12) Patent Application Publication
(10) Pub. No.: US 2010/0207129 A1
(43) Pub. Date: Aug. 19, 2010

(54) LIGHT EMITTING DIODE LIGHT SOURCE FOR EMITTING POLARIZED LIGHT

(75) Inventors: AN-CHI WEI, Chu-Nan (TW); NAI-WEN ZHANG, Chu-Nan (TW); CHIH-MING LAI, Chu-Nan (TW)

Correspondence Address: PCE INDUSTRY, INC.;ATT. Steven Reiss, 288 SOUTH MAYO AVENUE, CITY OF INDUSTRY, CA, 91789, US

(73) Assignee: FOXSEMICON INTEGRATED TECHNOLOGY, INC., Chu-Nan (TW)

(21) Appl. No.: 12/649,481

(22) Filed: Dec. 30, 2009

(30) Foreign Application Priority Data
Feb. 17, 2009 (CN) 200910300441.2

(51) Int. Cl. H01L 33/60; H01L 33/46

(52) U.S. Cl. 257/88; 313/500; 257/E33.055

(57) ABSTRACT

An exemplary light emitting diode (LED) light source includes a frame and light emitting units. The frame includes a supporting surface having a curved surface and one or more receiving holes configured in the curved surface. Each of the light emitting units is received in a respective receiving hole. Each of the light emitting units includes an LED die for generating light of two polarization states, a reflective polarizer for preferentially reflects one polarization state back into the LED die and preferentially transmitting the other polarization state out of the light emitting unit, a polarization converting film for converting the reflected light of the first polarization state into light of the second polarization state, and a reflective film for reflecting light of the converted second polarization state to the reflective polarizer.

### BACKGROUND

1. Technical Field

The present disclosure generally relates to light emitting diode (LED) light sources, and particularly, to an LED light source configured for emitting much polarized light.

2. Description of Related Art

Light emitting diodes (LEDs) have been used as light sources in products such as liquid crystal displays (LCDs) due to their high luminous efficiency and high color performance. However, since an LCD can only receive light in a unidirectional polarization state, the LCD may lose a big portion of the light energy provided by the LEDs. As a result, the quality and efficiency of the display provided by the LCD may be greatly reduced. Furthermore, the LEDs are usually arranged on a single planar circuit board in a backlight module. This means the light emitted from the LEDs is output from the backlight module via a common light exit surface of the backlight module. As such, the light output from the backlight module is apt to propagate in substantially a single direction only. This may be unsatisfactory for LCDs that require a wide light distribution range.

Therefore, what is needed is an LED illumination device that overcomes the described limitations.

### BRIEF DESCRIPTION OF THE DRAWINGS

Many aspects of the disclosed LED light source can be better understood with reference to the following drawings. The components in the drawings are not necessarily drawn to scale, the emphasis instead being placed upon clearly illustrating the principles of the present LED light source. Moreover, in the drawings, like reference numerals designate corresponding parts throughout the several views, and all the views are schematic.

FIG. 1 is an isometric view of an LED light source, according to a first embodiment.

FIG. 2 is a cross-sectional view of the LED light source of FIG. 1, taken along line II-II thereof.

FIG. 3 is an isometric view of a frame of the LED light source of FIG. 1.

FIG. 4 is an isometric view of a frame of an LED light source which is a variation of the LED light source according to the first embodiment.

FIG. 5 is an isometric view of an LED light source, according to a second embodiment.

FIG. 6 is an isometric view of a frame of the LED light source of FIG. 4.

FIG. 7 is an isometric view of an LED light source, according to a third embodiment.

FIG. 8 is an isometric view of a frame of the LED light source of FIG. 6.

### DETAILED DESCRIPTION

Reference will now be made to the drawings to describe various embodiments of the present light emitting diode light source, in detail.

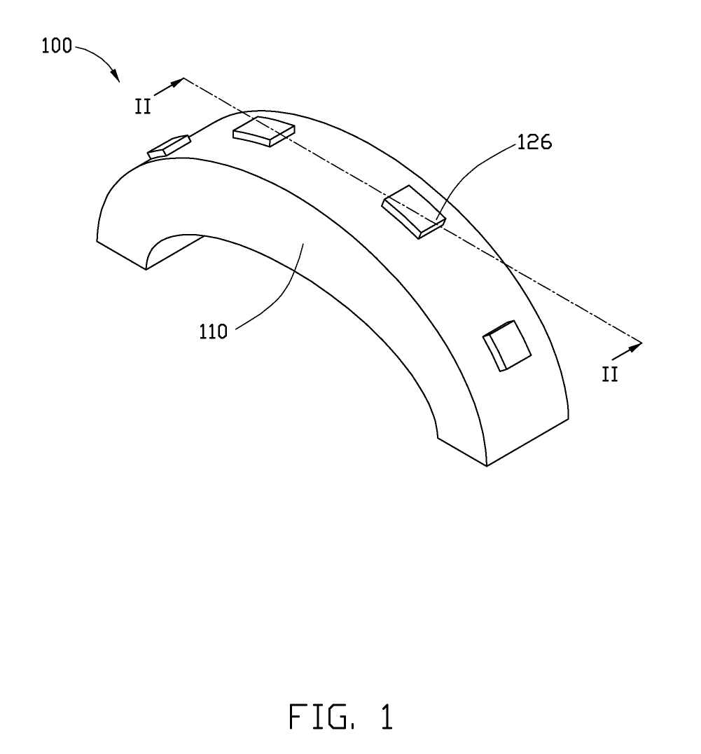

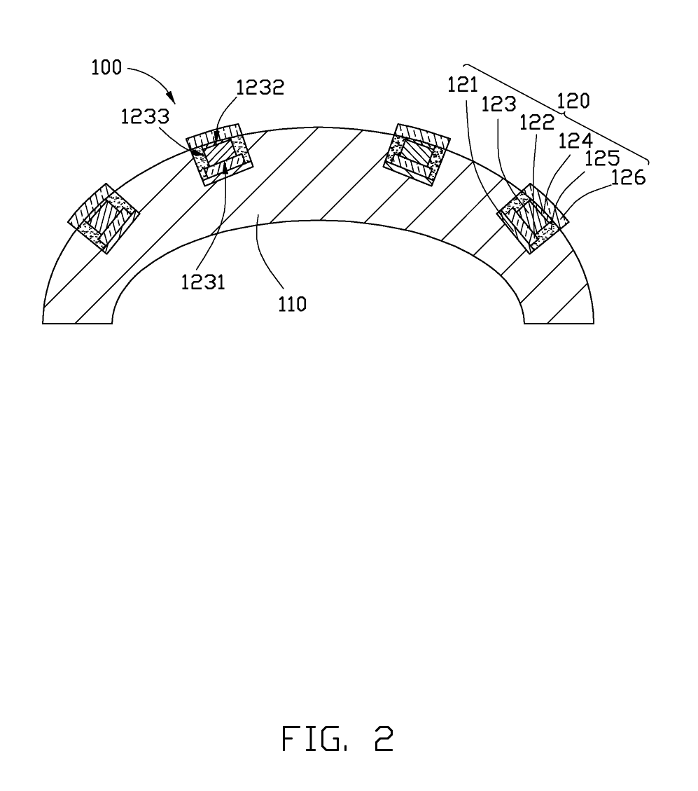

Referring to FIG. 1 and FIG. 2, a light emitting diode (LED) light source 100, according to a first embodiment, includes a frame 110 and a plurality of light emitting units 120.

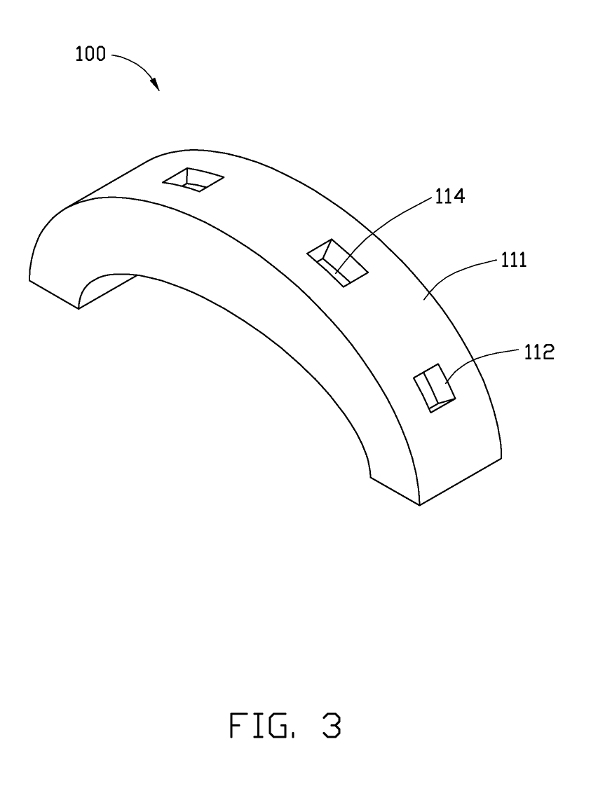

Referring also to FIG. 3, the frame 110 has an arc-like configuration. The frame 110 includes a supporting surface 111. The supporting surface 111 has a plurality of receiving holes 112 defined therein. The receiving holes 112 are blind holes, and are configured for receiving the light emitting units 120. Each receiving hole 112 is bounded by a bottom surface 114. The supporting surface 111 is a convex curved surface in this embodiment.

Each of the light emitting units 120 is received in a respective receiving hole 112. Each light emitting unit 120 includes a reflective film 121, a polarization converting film 122, an LED die 123, and a reflective polarizer 126.

The reflective film 121 is disposed on the bottom surface 114 of the receiving hole 112. The reflective film 121 can be made of metal, for example gold, silver, aluminum, chromium or nickel.

The polarization converting film 122 is formed on the reflective film 121. The polarization converting film 122 can be a quarter wave plate made of quartz, sapphire, lithium niobate or calcite. The polarization converting film 122 can have a rough surface formed by etching or rubbing. The polarization converting film 122 has an area equal to or smaller than that of the reflective film 121.

The LED die 123 is arranged on the polarization converting film 122. The LED die 123 includes a bottom surface 1231, a top light exit surface 1232, and a plurality of side surfaces 1233 adjoining both the bottom surface 1231 and the light exit surface 1232. The bottom surface 1231 contacts the polarization converting film 122. The LED die 123 can be a red LED chip, a blue LED chip, a green LED chip, or a white LED chip.

The reflective polarizer 126 is arranged facing toward the light exit surface 1232 of the LED die 123. The reflective polarizer 126 can be arranged inside the receiving hole 112, together with the LED die 123. Alternatively, the reflective polarizer 126 can be arranged at an opening of the receiving hole 112 and cover such opening. In this embodiment, the reflective polarizer 126 is arranged at the opening of the receiving hole 112 and covers the opening. The reflective polarizer 126 can be a Vikuiti™ dual brightness enhancement film (DBEF) produced by the 3M Company of the United States.

The LED die 123 is configured for emitting light of two polarization states, i.e., a first polarization state and a second polarization state. The light exit surface 1232 outputs the light emitted by the LED die 123 toward the reflective polarizer 126. The reflective polarizer 126 preferably reflects light of the first polarization state back toward the LED die 123, and preferably transmits light of the second polarization state out of the light emitting unit 120. The light of the first polarization state reflected by the reflective polarizer 126 passes back through the LED die 123, and through the polarization converting film 122 once, and is then reflected by the reflective film 121, and passes through the polarization converting film 122 again. After passing through the polarization converting film 122 twice, the light of the first polarization state is converted to the second polarization state. Thereafter, the converted light is incident on the reflective polarizer 126, and the reflective polarizer 126 transmits the converted light out of the light emitting unit 120.

The LED light source 100 has at least the following advantages. Firstly, recycling of light within the light emitting unit 120 together with the polarization conversion mechanisms of the light emitting unit 120 can enhance the efficiency and brightness of the polarized light output from the light emitting unit 120. Secondly, because the receiving holes 112 are arranged along the curved supporting surface 111 and not along a common plane, the light emitting units 120 are correspondingly arranged in a curved pattern. Therefore, the light emitted from the light emitting units 120 is output from respective different output planes. Thus the LED light source 100 has a predetermined wide light distribution range. In addition, the predetermined light distribution range needed for the LED light source 100 depends on the requirements of different applications. The particular light distribution range needed for any given LED light source 100 can be achieved by altering the configuration of the curved supporting surface 111 in a process of manufacturing the frame 110.

Furthermore, each light emitting unit 120 can include a fluorescence film 124 for changing the color of the light output from the light emitting unit 120. The fluorescence film 124 can be formed on the light exit surface 1232 of the LED die 123. The fluorescence film 124 can be made of a phosphor substance comprising sulfides, aluminates, oxides, or nitrides.

Moreover, each receiving hole 112 can have a filling substance (potting) 125 filled in the remaining space thereof not occupied by the light emitting unit 120. The filling substance 125 can be resin, silicone or polyethylene terephthalate (PET).

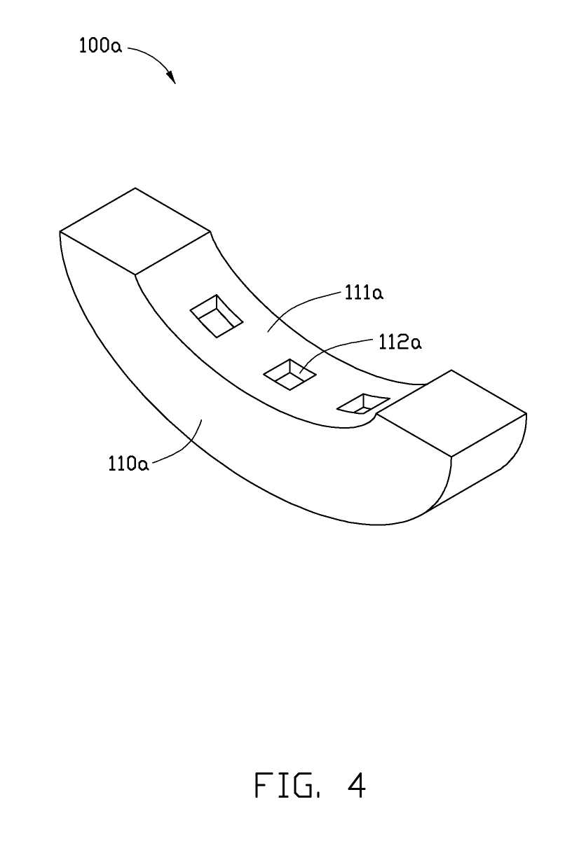

Referring to FIG. 4, in a variation of the first embodiment, an LED light source 100a includes a frame 110a that has an arc-like configuration. The frame 110a has a supporting surface 111a. The supporting surface 111a is a concave curved surface. The supporting surface 111a has a plurality of receiving holes 112a defined therein.

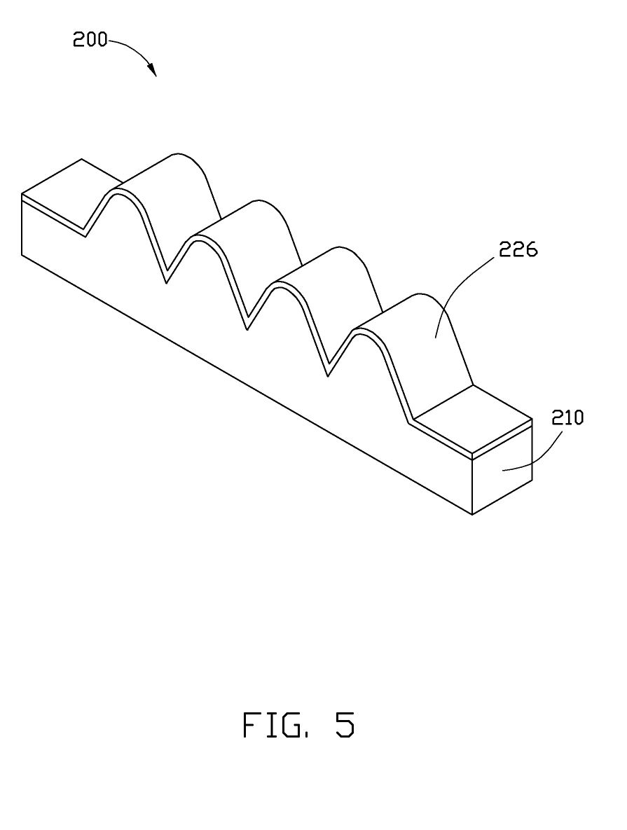

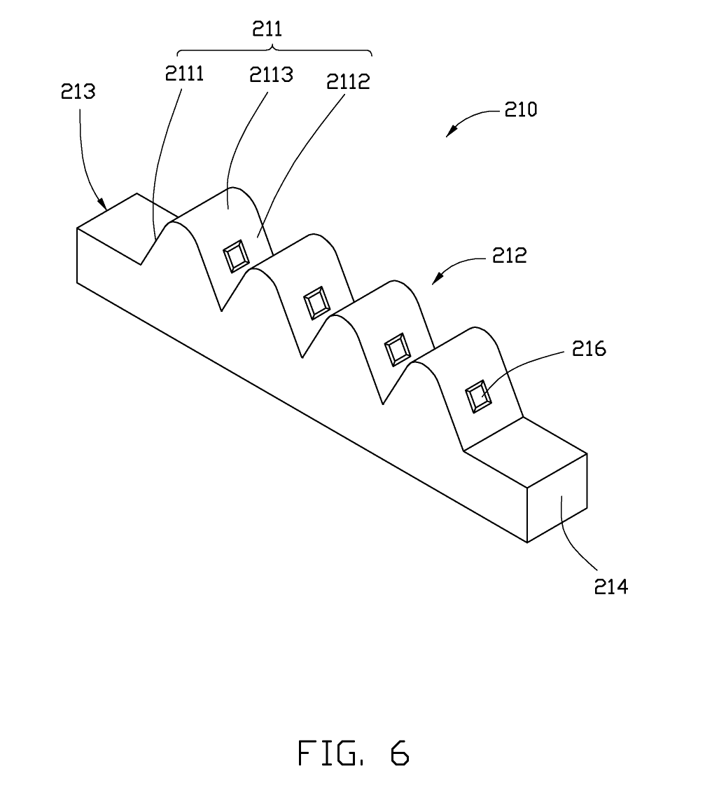

Referring to FIG. 5 and FIG. 6, a light emitting diode (LED) light source 200 according to a second embodiment is shown. The LED light source 200 has a configuration generally similar to the above-described LED light source 100. The LED light source 200 includes a frame 210 and a plurality of light emitting units (not shown). The frame 210 has a configuration different from the frame 110 of the LED light source 100.

The frame 210 includes a prism-like base portion, and a plurality of successive protrusions 211 at the top of the base portion. Each protrusion 211 includes a first side surface 2111, a second side surface 2112, and a top surface 2113 smoothly interconnecting the first side surface 2111 and the second side surface 2112. In the illustrated embodiment, each of the first side surface 2111 and the second side surface 2112 is substantially planar. The protrusions 211 are continuously connected in sequence and cooperatively form a generally wave shaped supporting surface 212. Thus the protrusions 211 correspond to peaks of the wave shape. In the illustrated embodiment, the second side surfaces 2112 are substantially parallel to each other. A junction between each two adjacent protrusions 211 is an angular junction. Each protrusion 211 has a receiving hole 216 formed in the second side surface 2112. Each receiving hole 216 is a blind hole. In alternative embodiments, the receiving hole 216 is not limited to being formed in the second side surface 2112. The receiving hole 216 can instead be formed in the first side surface 2111 or in the top surface 2113 of each protrusion 211.

The LED light source 200 further includes a reflective polarizer 226, which is different from the reflective polarizers 126 of the LED light source 100. That is, the reflective polarizer 226 is formed on substantially the whole of the supporting surface 212.

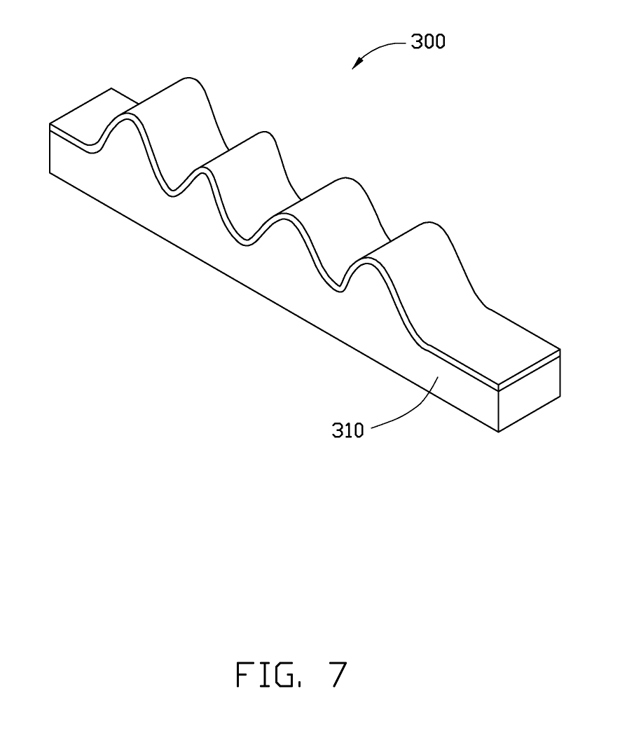

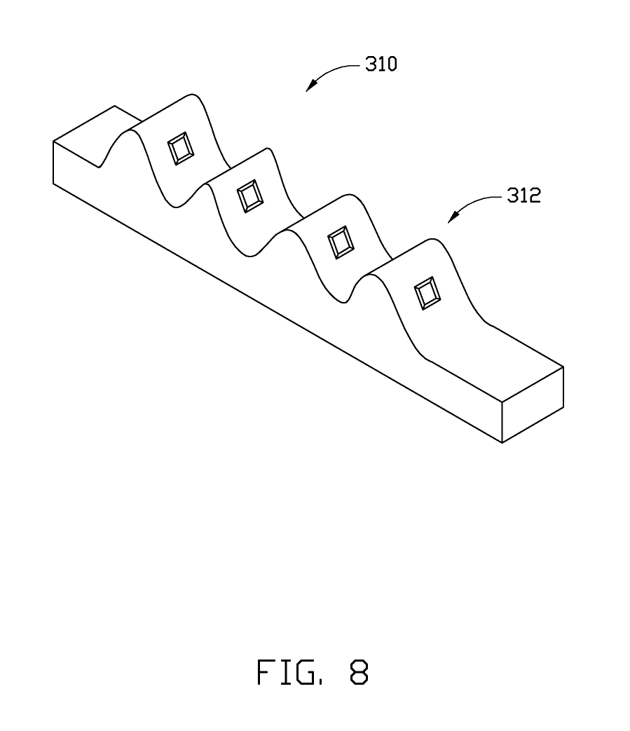

Referring to FIG. 7 and FIG. 8, a light emitting diode (LED) light source 300 according to a third embodiment is shown. The LED light source 300 has a configuration generally similar to the above-described LED light source 200. The LED light source 300 includes a frame 310 having a plurality of protrusions 312. A junction between each two adjacent protrusions 312 is smoothly curved. At least one of the protrusions 312 has a shape and/or size different from that of the other protrusions 312. For example, in the illustrated embodiment, one of the protrusions 312 is narrower than the other protrusions 312. Accordingly, the side surface with the receiving hole of the narrow protrusion 312 is non-parallel relative to the side surfaces with the receiving holes of the other protrusions 312.

In each of the above-described LED light sources 100, 100a, 200, 300, the light emitting units received in the respective receiving holes are arranged along different surfaces and are not in a common plane. Therefore, the light emitted from the light emitting units is output from respective different output planes. Thus, each LED light source 100, 100a, 200, 300 has a predetermined wide light distribution range. Furthermore, the predetermined light distribution range needed for each LED light source 100, 100a, 200, 300 depends on the requirements of different applications. The particular light distribution range needed for any given LED light source 100, 100a, 200, 300 can be achieved by altering the configuration of the supporting surface in a process of manufacturing the frame 110, 110a, 210, 310.

Finally, it is to be understood that the above-described embodiments are intended to illustrate rather than limit the disclosure. Variations may be made to the embodiments without departing from the spirit of the invention as claimed. The above-described embodiments illustrate the scope of the disclosure but do not restrict the scope of the disclosure.

What is claimed is:

1. A light emitting diode (LED) light source, comprising:
a frame with a supporting surface, the supporting surface comprising a plurality of surface portions, each surface portion defining a plane, the plane of each surface portion being noncoplanar relative to the plane of at least one other surface portion, and the frame defining a plurality of receiving holes at the surface portions; and
a plurality of light emitting units each at least partially received in a respective receiving hole, each of the light emitting units comprising:
a reflective film arranged at a bottom of the receiving hole;
a polarization converting film arranged on the reflective film;
an LED die arranged on the polarization converting film, the LED die comprising a light emitting surface facing away from the polarization converting film; and
a reflective polarizer arranged generally adjacent the light emitting surface of the LED die;
wherein the LED die is configured to generate light of a first polarization state and a second polarization state and emit the light toward the reflective polarizer, the reflective polarizer is configured to reflect the light of the first polarization state back toward the LED die and transmit the light of the second polarization state, and the polarization converting film is positioned to receive the light of the first polarization state reflected by the reflective polarizer and in cooperation with the reflective film is configured to convert the light of the first polarization state into light of the second polarization state and transmit the converted light to the reflective polarizer.

2. The LED light source according to claim 1, wherein the light emitting unit further comprises a fluorescence film arranged between the LED die and the reflective polarizer, the fluorescence film configured for changing color of the light output from the light emitting unit.

3. The LED light source according to claim 1, wherein the supporting surface is in the form of a single, elongate curved surface.

4. The LED light source according to claim 3, wherein the curved surface is one of a convex surface and a concave surface.

5. The LED light source according to claim 1, wherein the supporting surface is in the form of a single, elongate generally wave shaped surface, the wave shaped surface comprises a plurality of peaks, the frame comprises a plurality of protrusions corresponding to the plurality of peaks, each of the protrusions has a first side and an opposite second side, the first sides of the protrusions correspond to each other in orientation, the second sides of the protrusions correspond to each other in orientation, and the surface portions are located at the second sides of the protrusions, respectively.

6. The LED light source according to claim 5, wherein the second sides of the protrusions are substantially planar, and are substantially parallel to each other.

7. The LED light source according to claim 5, wherein the second side of at least one of the protrusions is non-parallel relative to the second side of at least one other protrusion.

8. The LED light source according to claim 1, wherein for each of the light emitting units, the reflective polarizer is formed on the supporting surface and covers the respective receiving hole.

9. The LED light source according to claim 8, wherein the reflective polarizers of the light emitting units are portions of a single reflective polarizer layer that covers a whole section of the supporting surface which spans all the receiving holes.

10. The LED light source according to claim 1, wherein for each of the light emitting units, the reflective polarizer is formed in the respective receiving hole.

11. A light emitting diode (LED) light source, comprising:
a frame comprising at least one bulge, the at least one bulge comprising a plurality of surface portions, the frame defining a same plurality of receiving holes at the surface portions, each of the receiving holes defining a central axis, the central axis of each receiving hole being nonparallel with respect to the central axis of at least one other receiving hole; and
a same plurality of light emitting units each being at least partially received in a respective receiving hole, each of the light emitting units comprising:
an LED die configured for generating light of a first polarization state and a second polarization state and outputting the light in the general direction of the surface portion;
a reflective polarizer located at the light output side of the LED die and configured for reflecting light of the first polarization state back toward the LED die and transmitting light of the second polarization state out of the light emitting unit;
a polarization converting film located at a side of the LED die opposite to the light output side, and configured for receiving the light of the first polarization state reflected by the reflective polarizer and with two passes of such light of the first polarization state through the polarization converting film converting such light of the first polarization state into light of the second polarization state; and
a reflective film located at a side of the polarization converting film opposite to the side of the polarization converting film where the LED die is located, and configured for reflecting the light of the first polarization state reflected by the reflective polarizer and passed through the polarization converting film back to the polarization converting film.

12. The LED light source according to claim 11, wherein the light emitting unit further comprises a fluorescence film arranged between the LED die and the reflective polarizer, the fluorescence film configured for changing color of the light output from the light emitting unit.

13. The LED light source according to claim 11, wherein the supporting surface comprises a plurality of arc surfaces alternately adjoined together along a first direction.

14. The LED light source according to claim 13, wherein at least one of the arc surfaces has a shape different from the others.

15. The LED light source according to claim 11, wherein the reflective polarizer of each light emitting unit is formed on the supporting surface and covers the respective receiving hole.

16. The LED light source according to claim 15, wherein the reflective polarizers of the light emitting units are portions of a single reflective polarizer layer that covers a whole section of the supporting surface which spans all the receiving holes.
